(19) United States
(12) Patent Application Publication
(10) Pub. No.: US 2024/0290655 A1
(43) Pub. Date: Aug. 29, 2024

(54) SELECTIVE VIA-FILL WITH CONFORMAL SIDEWALL COVERAGE

(71) Applicant: Applied Materials, Inc., Santa Clara, CA (US)

(72) Inventors: Zheng JU, Sunnyvale, CA (US); Zhiyuan WU, San Jose, CA (US); Jiajie CEN, Santa Clara, CA (US); Feng Q. LIU, San Jose, CA (US); Feng CHEN, San Jose, CA (US)

(21) Appl. No.: 18/115,561

(22) Filed: Feb. 28, 2023

(51) Int. Cl. H01L 21/768; H01L 23/522

(52) U.S. Cl. CPC H01L 21/76844; H01L 21/76846; H01L 21/76879; H01L 23/5226; H01L 21/76862; H01L 23/53238; H01L 23/53266

(57) ABSTRACT

A method of selectively filling a via with a simultaneous liner deposition in a semiconductor structure includes forming a passivation layer selectively on an exposed surface of a conductive layer within a via formed in a dielectric layer formed over the conductive layer, forming a barrier layer selectively on inner sidewalls of the via and a trench formed in the dielectric layer, selectively filling the via with a first conductive material at least partially and simultaneously depositing the first conductive material on the barrier layer on the inner sidewalls of the via and the trench, to form a liner on the inner sidewalls of the via and the trench, and filling the remaining of the via and the trench with a second conductive material.

### BACKGROUND

### Field

Embodiments described herein generally relate to semiconductor device fabrication, and more particularly, to methods of selectively filling a via and forming a conformal liner on inner sidewalls of the via and a trench structure.

### Description of the Related Art

In copper (Cu) interconnects used in silicon integrated circuits (ICs), barrier metal layers are typically used to surround copper interconnects to prevent diffusion and other adverse interactions in surrounding materials. At a small device dimension, such as via bottom critical dimension (CD) of less than 12 nm, typical barrier metal layers and liner layers on sidewalls of the via can be thicker than 3 nm, leaving a small volume within the via to fill with copper and thus leading to a high via resistance. Scaling of a barrier metal layer to below 1 nm and a liner layer to below 2 nm both face challenges in terms of continuity of a barrier metal layer and a liner layer, metal barrier property, adhesion of a liner layer to copper, and filling of a via with copper.

Therefore, there is a need for methods of selectively filling a via with conductive material to reduce via resistance and reduce an aspect ratio of the via to fill with copper in a dual damascene process forming interconnect structures.

### SUMMARY

Embodiments of the present disclosure provide a method of selectively filling a via with a simultaneous liner deposition in a semiconductor structure. The method includes forming a passivation layer selectively on an exposed surface of a conductive layer within a via formed in a dielectric layer formed over the conductive layer, forming a barrier layer selectively on inner sidewalls of the via and a trench formed in the dielectric layer, selectively filling the via with a first conductive material at least partially and simultaneously depositing the first conductive material on the barrier layer on the inner sidewalls of the via and the trench, to form a liner on the inner sidewalls of the via and the trench, and filling the remaining of the via and the trench with a second conductive material.

Embodiments of the present disclosure also provide a method of selectively filling a via with a liner deposition in a semiconductor structure. The method includes forming a passivation layer selectively on an exposed surface of a conductive layer within a via formed in a dielectric layer formed over the conductive layer, forming a barrier layer selectively on inner sidewalls of the via, selectively filling the via with a first conductive material at least partially, without depositing the first conductive material on the barrier layer on the inner sidewalls of the via, depositing a second conductive material selectively on the barrier layer on the inner sidewalls of the via and a trench formed in the dielectric layer, to form a liner on the inner sidewalls of the via and the trench, and filling the remaining of the via and the trench with a third conductive material.

Embodiments of the present disclosure further provide a method of selectively filling a via with a simultaneous liner deposition in a semiconductor structure. The method includes selectively filling a via in a dielectric layer formed over a conductive layer with a first conductive material at least partially and simultaneously forming a liner layer on inner sidewalls of the via and a trench formed in the dielectric layer, and filling the remaining of the via with a second conductive material.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a processing system that may be utilized to perform a deposition process according to one embodiment.

FIG. 2 is a process flow diagram of a method of selectively filling a via with a liner in a semiconductor structure according to a first embodiment of the present disclosure.

FIGS. 3A, 3B, 3C, 3D, 3E, 3F, and 3G are cross-sectional views of a portion of the interconnect structure corresponding to various states of the method of FIG. 2.

FIG. 4 is a process flow diagram of a method of selectively filling a via with a liner in a semiconductor structure according to a second embodiment of the present disclosure.

FIGS. 5A and 5B are cross-sectional views of a portion of the interconnect structure corresponding to various states of the method of FIG. 4.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Methods for selectively filing a via at least partially while conformally depositing a liner on sidewalls of the via and a trench are provided. Proposed approaches enable selective via fill or partial fill during conformal liner deposition. In methods provided herein, conductive material, such as ruthenium (Ru), cobalt (Co), molybdenum (Mo), or tungsten (W), is deposited, selectively or at a faster deposition rate, at a bottom of the via while deposited at a slower deposition rate, on the sidewalls of the via (e.g., low k dielectric (SiCOH), silicon dioxide (SiO₂) or silicon nitride (Si₃N₄)). Due to the filling of the bottom of the via with conductive material, overall via resistance is reduced and the remaining via filling with copper is less challenging.

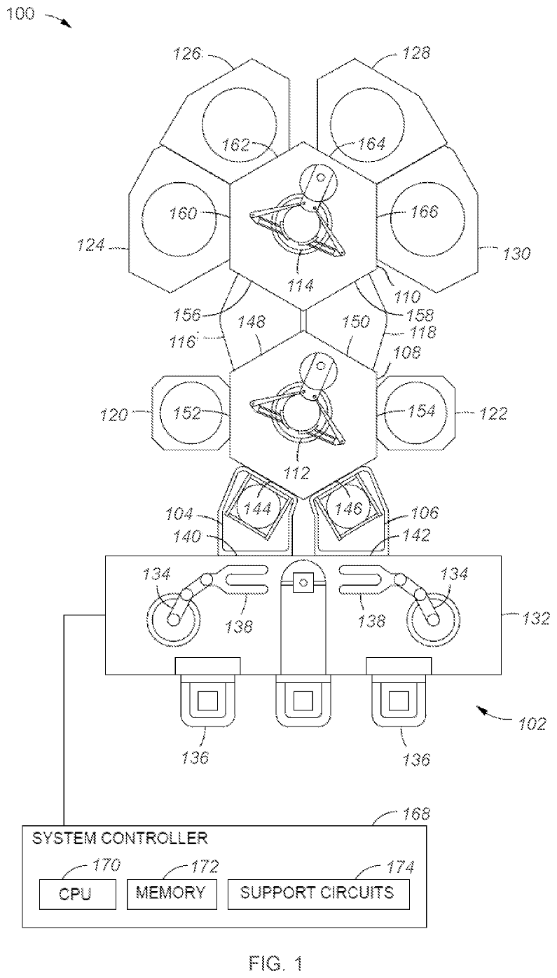

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber, Volta™ CVD/ALD chamber, or Encore™ PVD chambers available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

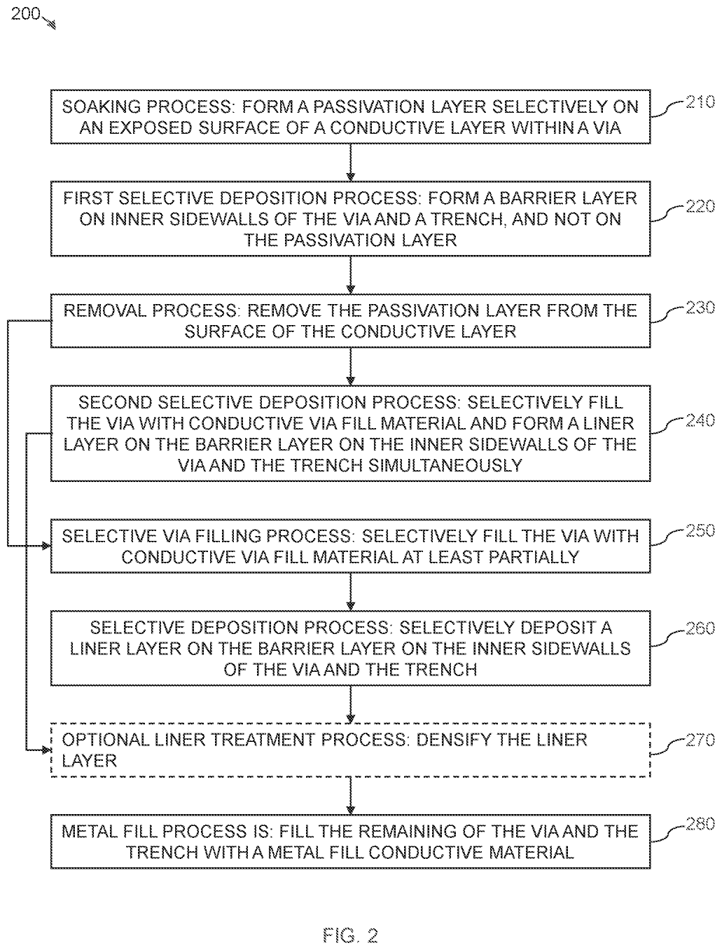

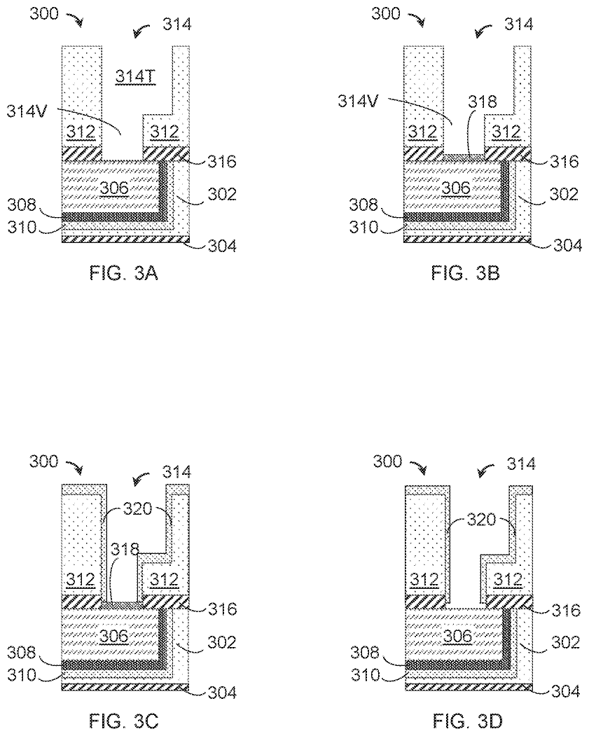

FIG. 2 depicts a process flow diagram of a method 200 of selectively filling a via with a liner in a semiconductor structure, such as an interconnect structure 300 formed on a substrate according to a first embodiment of the present disclosure. FIGS. 3A, 3B, 3C, 3D, 3E, 3F, and 3G are cross-sectional views of a portion of the interconnect structure 300 corresponding to various states of the method 200. It should be understood that FIGS. 3A, 3B, 3C, 3D, 3E, 3F, and 3G illustrate only partial schematic views of the interconnect structure 300, and the interconnect structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 3A, the interconnect structure 300 includes a first dielectric layer 302 formed on a substrate (not shown). The first dielectric layer 302 may be formed of a dielectric material, such as low k dielectric (SiCOH), silicon dioxide (SiO₂), silicon nitride (Si₃N₄), silicon carbide (SiC), aluminum oxide (Al₂O₃), or aluminum nitride (AlN). A first etch stop layer 304 may be disposed between the first dielectric layer 302 and the substrate. The interconnect structure 300 further includes a conductive layer 306 embedded within the first dielectric layer 302 and separated from the first dielectric layer 302 by a liner layer 308 and a barrier layer 310. The conductive layer 306 may be formed of copper (Cu), cobalt (Co), molybdenum (Mo), tungsten (W), or ruthenium (Ru). The liner layer 308 may be formed of ruthenium (Ru) and cobalt (Co), or RuCo. The barrier layer 310 may be formed of tantalum nitride (TaN) or doped tantalum nitride (TaN). The interconnect structure 300 further includes a second dielectric layer 312, having one or more features 314, such as a via 314V and a trench 314T formed therein, over the first dielectric layer 302 and the conductive layer 306. The second dielectric layer 312 may be formed of the same material as the first dielectric layer 302, such as low k dielectric (SiCOH), silicon dioxide (SiO₂), silicon nitride (Si₃N₄), silicon carbide (SiC), aluminum oxide (Al₂O₃), or aluminum nitride (AlN). In another embodiment, the second dielectric layer 312 may be formed of a different material from the first dielectric layer 302, while maintaining the same low-k properties. A second etch stop layer 316 may be disposed between the second dielectric layer 312 and the first dielectric layer 302. Within the via 314V, a surface of the conductive layer 306 is exposed.

The method 200 begins with block 210, in which a soaking process is performed to form a passivation layer 318 selectively on the exposed surface of the conductive layer 306 within the via 314V, as shown in FIG. 3B. The soaking process may be performed in a processing chamber, such as the processing chamber 124, 126, 128, or 130 shown in FIG. 1.

The passivation layer 318 may be formed of a self-assembled monolayer (SAM) of organic molecules. In the soaking process, the interconnect structure 300 is soaked in a gas precursor including an unsaturated hydrocarbon, at a temperature of less than about 450° C. and a pressure of less than about 80 Torr for a time duration of greater than about 10 seconds, with a flow rate of the precursor of between 50 sccm and about 600 sccm. In some embodiments, a liquid precursor is used in the soaking process. In the soaking process, organic molecules in the precursor are absorbed only on a metal surface, such as the exposed surface of the conductive layer 306. The passivation layer 318 may act as a block layer that suppresses nucleation or growth of a subsequent material deposition thereon.

In block 220, a first selective deposition process is performed to form a barrier layer 320 on inner sidewalls of the via 314V and the trench 314T, and not on the passivation layer 318, as shown in FIG. 3C. The first selective deposition process may include an ALD process in a processing chamber, such as the processing chamber 124, 126, 128, or 130 shown in FIG. 1.

The barrier layer 320 may be formed of tantalum nitride (TaN) or doped tantalum nitride (TaN), metal doped TaN, titanium nitride (TiN), tungsten nitride (WN), or tungsten nitride carbide (WCN). The selectivity in the first selective deposition process may arise from differences in nucleation of the barrier layer 320 on exposed surfaces of the second dielectric layer 312 (e.g., silicon dioxide (SiO₂) or silicon nitride (Si₃N₄)) and on the passivation layer 318. In some embodiments, the barrier layer 320 is deposited by sequentially exposing the interconnect structure 300 to a metal precursor and a reactant.

In block 230, a removal process is performed to remove the passivation layer 318 from the surface of the conductive layer 306, as shown in FIG. 3D. The removal process may include a dry etch process in an etch chamber, such as the processing chamber 122 shown in FIG. 1.

The removal process may include an anisotropic remote plasma assisted dry etch process, such as a reactive ion etching (RIE) process, using a plasma formed from a gas including argon (Ar), helium (He), nitrogen (N₂), hydrogen (H₂), ammonia (NH₃), or a combination thereof. The plasma effluents directionally bombard and remove the passivation layer 318.

In block 240, a second selective deposition process is performed to selectively fill the via 314V with conductive via fill material 322 at least partially and form a liner layer 324 on the barrier layer 320 on the inner sidewalls of the via 314V and the trench 314T simultaneously with or without the assistance of a passivation layer (SAM), as shown in FIG. 3E. The second selective deposition process may include any appropriate deposition process, such as atomic layer deposition (ALD), chemical vapor deposition (CVD), or a wet process including electrical plating, in a processing chamber, such as the processing chamber 124, 126, 128, or 130 shown in FIG. 1.

In the second selective deposition process, the interconnect structure 300 is exposed to a precursor including the conductive via fill material 322, which grows from the exposed surface of the conductive layer 306 (e.g., copper (Cu), cobalt (Co), molybdenum (Mo), tungsten (W), or ruthenium (Ru)) at a faster rate, for example, about ten times faster, than that from the exposed surface of the barrier layer 320 (e.g., tantalum nitride (TaN)). Thus, the via 314V is filled with the conductive fill material 322 at least partially, while a thin conformal liner layer 324 of the same conductive fill material 322 is formed on the barrier layer 320 on the sidewalls of the via 314V and the trench 314T. The conductive via fill material 322 may be ruthenium (Ru), cobalt (Co), molybdenum (Mo), or tungsten (W).

Alternatively to the second deposition process to simultaneously fill the via 314V and form the barrier layer 320 in block 240, a selective via filling process to selectively fill the via 314V at least partially in block 250 and a selective deposition process to form the liner layer 324 in block 260 may be performed sequentially, with or without the assistance of a passivation layer, similar to the passivation layer 318. The selective via filling process and the selective deposition process may include any appropriate deposition process, such as atomic layer deposition (ALD), chemical vapor deposition (CVD), or a wet process including electrical plating, in a processing chamber, such as the processing chamber 124, 126, 128, or 130 shown in FIG. 1.

In block 250, the via 314V is selectively filled with conductive via fill material 322 at least partially, as shown in FIG. 3F, without depositing conductive via fill material 322 on the barrier layer 320 on the sidewalls of the via 314V and the trench 314T. The selectivity in the selective via filling process in block 250 arises from differences in nucleation or growth of the conductive fill material 322 on the exposed surface of the conductive layer 306 (e.g., copper (Cu), cobalt (Co), molybdenum (Mo), tungsten (W), or ruthenium (Ru)) and on the exposed surface of the barrier layer 320 (e.g., tantalum nitride (TaN)). In some embodiments, a passivation layer (not shown), similar to the passivation layer 318, is formed on the barrier layer 320, to prevent growth of the conductive fill material 322 on the sidewalls of the via 314V and the trench 314T in the via filling process in block 250, and removed from the barrier layer 320, subsequent to the via filling process. The conductive via fill material 322 may be ruthenium (Ru), cobalt (Co), molybdenum (Mo), or tungsten (W).

In block 260, the liner layer 324 is selectively deposited on the barrier layer 320 on the inner sidewalls of the via 314V and the trench 314T, as shown in FIG. 3E. The liner layer 324 may be formed of the same conductive material as the conductive via fill material 322, or a different conductive material such as ruthenium (Ru), cobalt (Co), molybdenum (Mo), or tungsten (V).

In block 270, an optional liner treatment process is performed to densify the liner layer 324. The optional liner treatment process may include a plasma treatment or a gas soak. The plasma treatment may use a capacitively coupled plasma (CCP) or an inductively coupled plasma (ICP) process in a processing chamber, such as the processing chamber 122 shown in FIG. 1. In the gas soak, the interconnect structure 300 is soaked in a gas such as hydrogen (H₂) or ammonia (NH₃).

In block 280, a metal fill process is performed to fill the remaining of the via 314V and the trench 314T with a metal fill conductive material 326, as shown in FIG. 3F. The metal fill conductive material 326 may be copper (Cu), cobalt (Co), ruthenium (Ru), or molybdenum (Mo). The metal fill process may include a chemical vapor deposition (CVD) process, a physical vapor deposition (PVD), and an electro plating process, in a processing chamber, such as the processing chamber 124, 126, 128, or 130 shown in FIG. 1.

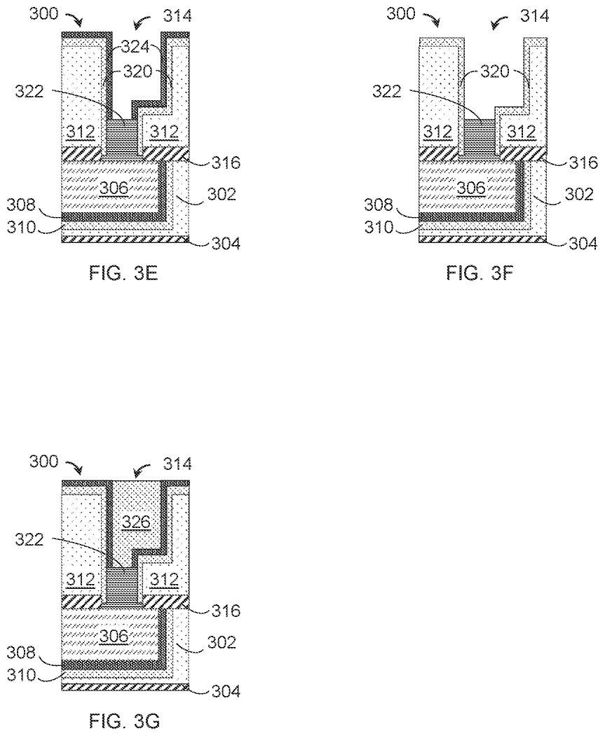

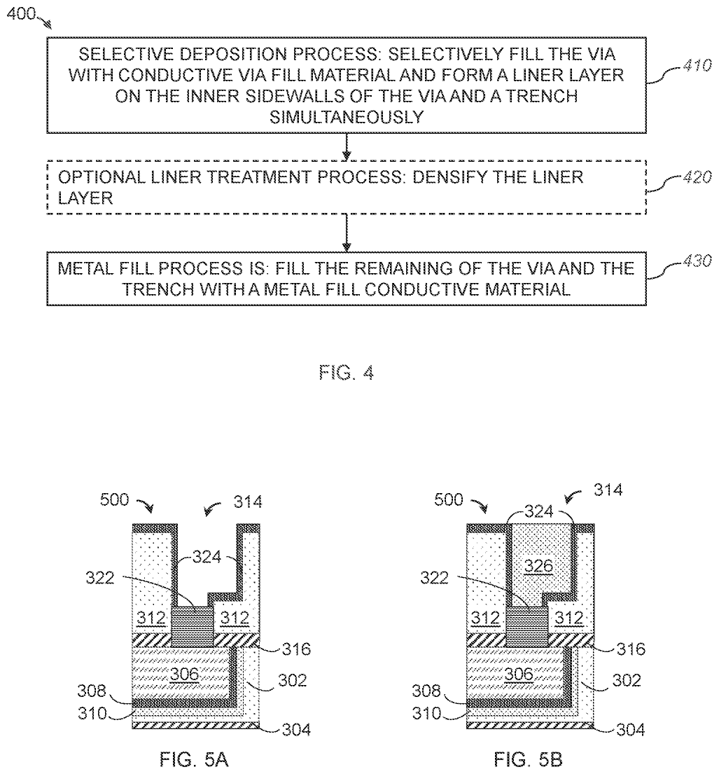

FIG. 4 depicts a process flow diagram of a method 400 of selectively filling a via with a liner in a semiconductor structure, such as an interconnect structure 500 formed on a substrate according to a second embodiment of the present disclosure. In the second embodiment, a passivation layer such as the passivation layer 318 or a barrier layer 320, which enhances selectivity in depositing various layers are not used. The selectivity in filing a via and depositing a liner on inner sidewalls of the via relies on the difference in nucleation or growth of conductive material on a metal surface and on a dielectric surface. FIGS. 5A and 5B are cross-sectional views of a portion of the interconnect structure 500 corresponding to various states of the method 400. It should be understood that FIGS. 5A and 5B illustrate only partial schematic views of the interconnect structure 500, and the interconnect structure 500 may contain any number of transistor sections and additional materials having aspects as illustrated in the figures. It should also be noted that although the method illustrated in FIG. 4 is described sequentially, other process sequences that include one or more operations that have been omitted and/or added, and/or has been rearranged in another desirable order, fall within the scope of the embodiments of the disclosure provided herein. In the following description, the same reference numerals are used for the components that are substantially the same as those of the first embodiment, and the description of repeated components may be omitted.

The method 400 begins with block 410, in which a selective deposition process is performed to selectively fill the via 314V with conductive via fill material 322 and form a liner layer 324 on the barrier layer 320 on the inner sidewalls of the via 314V and the trench 314T simultaneously, as shown in FIG. 5A. The selective deposition process may include any appropriate deposition process, such as atomic layer deposition (ALD), chemical vapor deposition (CVD), or a wet process including electrical plating, in a processing chamber, such as the processing chamber 124, 126, 128, or 130 shown in FIG. 1.

In the selective deposition process, the interconnect structure 300 is exposed to a precursor including the conductive via fill material 322, which grows from the exposed surface of the conductive layer 306 (e.g., copper (Cu), cobalt (Co), molybdenum (Mo), tungsten (W), or ruthenium (Ru)) at a faster rate, for example, about ten times faster, than that from the inner sidewalls of the via 314V and the trench 314T (e.g., e.g., silicon dioxide (SiO₂) or silicon nitride (Si₃N₄)). Thus, the via 314V is filled with the conductive fill material 322 at least partially, while a thin conformal liner layer 324 of the same conductive fill material 322 is formed on the inner sidewalls of the via 314V and the trench 314T. The conductive via fill material 322 may be ruthenium (Ru), cobalt (Co), molybdenum (Mo), or tungsten (W).

In block 420, an optional liner treatment process is performed to densify the liner layer 324. The optional liner treatment process in block 420 is generally the same as the optional liner treatment process in 270.

In block 430, a metal fill process is performed to fill the remaining of the via 314V and the trench 314T with a metal fill conductive material 326, as shown in FIG. 5B. The metal fill process in block 430 is generally the same as the metal fill process in block 280.

The embodiments described herein provide methods for selectively filing a via at least partially while conformally depositing a liner on sidewalls of the via. In the methods described herein, conformal deposition of a liner and selective filling of a via can be achieved at the same time. The selective filling of the via can be full or partial. Due to the via filling, the overall via resistance is reduced and the subsequent filling of copper to form an interconnect is less challenging since the aspect ratio of the remaining via is reduced.

While the foregoing is directed to embodiments of the present disclosure, other and further embodiments of the disclosure may be devised without departing from the basic scope thereof, and the scope thereof is determined by the claims that follow.

1. A method of selectively filling a via with a simultaneous liner deposition in a semiconductor structure, comprising:
forming a passivation layer selectively on an exposed surface of a conductive layer within a via formed in a dielectric layer formed over the conductive layer;
forming a barrier layer selectively on inner sidewalls of the via and a trench formed in the dielectric layer;
selectively filling the via with a first conductive material at least partially and simultaneously depositing the first conductive material on the barrier layer on the inner sidewalls of the via and the trench, to form a liner on the inner sidewalls of the via and the trench; and
filling the remaining of the via and the trench with a second conductive material.

2. The method of claim 1, further comprising:
removing the passivation layer from the surface of the conductive layer, subsequent to the forming of the barrier layer and prior to the selective filling of the via with the first conductive material.

3. The method of claim 1, further comprising:
performing a liner treatment process to densify the liner, the liner treatment process comprising a plasma treatment or a gas soak.

4. The method of claim 1, wherein the passivation layer comprises a self-assembled monolayer (SAM) of organic molecules.

5. The method of claim 1, wherein the dielectric layer comprises low k dielectric (SiOCH), silicon dioxide (SiO₂), silicon nitride (Si₃N₄), silicon carbide (SiC), aluminum oxide (Al₂O₃), or aluminum nitride (AlN).

6. The method of claim 1, wherein the barrier layer comprises tantalum nitride (TaN), metal doped TaN, titanium nitride (TiN), tungsten nitride (WN), or tungsten nitride carbide (WCN).

7. The method of claim 1, wherein the first conductive material comprises copper (Cu), cobalt (Co), molybdenum (Mo), tungsten (W), or ruthenium (Ru).

8. The method of claim 1, wherein the second conductive material comprises copper (Cu), cobalt (Co), ruthenium (Ru), or molybdenum (Mo).

9. A method of selectively filling a via with a liner deposition in a semiconductor structure, comprising:
forming a passivation layer selectively on an exposed surface of a conductive layer within a via formed in a dielectric layer formed over the conductive layer;
forming a barrier layer selectively on inner sidewalls of the via;
selectively filling the via with a first conductive material at least partially, without depositing the first conductive material on the barrier layer on the inner sidewalls of the via;
depositing a second conductive material selectively on the barrier layer on the inner sidewalls of the via and a trench formed in the dielectric layer, to form a liner on the inner sidewalls of the via and the trench; and
filling the remaining of the via and the trench with a third conductive material.

10. The method of claim 9, further comprising:
removing the passivation layer from the surface of the conductive layer, subsequent to the forming of the barrier layer and prior to the selective filling of the via with the first conductive material.

11. The method of claim 9, further comprising:
performing a liner treatment process to densify the liner, the liner treatment process comprising a plasma treatment or a gas soak.

12. The method of claim 9, wherein the passivation layer comprises a self-assembled monolayer (SAM) of organic molecules.

13. The method of claim 9, wherein the dielectric layer comprises low k dielectric (SiCOH), silicon dioxide (SiO₂), silicon nitride (Si₃N₄), silicon carbide (SiC), aluminum oxide (Al₂O₃), or aluminum nitride (AlN).

14. The method of claim 9, wherein the barrier layer comprises tantalum nitride (TaN), metal doped TaN, titanium nitride (TiN), tungsten nitride (WN), or tungsten nitride carbide (WCN).

15. The method of claim 9, wherein
the first conductive material comprises copper (Cu), cobalt (Co), molybdenum (Mo), tungsten (W), or ruthenium (Ru), and
the second conductive material comprises copper (Cu), cobalt (Co), molybdenum (Mo), tungsten (W), or ruthenium (Ru).

16. The method of claim 9, wherein
the third conductive material comprises copper (Cu), cobalt (Co), ruthenium (Ru), molybdenum (Mo).

17. A method of selectively filling a via with a simultaneous liner deposition in a semiconductor structure, comprising:
selectively filling a via in a dielectric layer formed over a conductive layer with a first conductive material at least partially and simultaneously forming a liner layer on inner sidewalls of the via and a trench formed in the dielectric layer; and
filling the remaining of the via with a second conductive material.

18. The method of claim 17, further comprising:
performing a liner treatment process to densify the liner, the liner treatment process comprising a plasma treatment or a gas soak.

19. The method of claim 17, wherein the dielectric layer comprises low k dielectric (SiCOH), silicon dioxide (SiO₂), silicon nitride (Si₃N₄), silicon carbide (SiC), aluminum oxide (Al₂O₃), or aluminum nitride (AlN).

20. The method of claim 17, wherein
the first conductive material comprises copper (Cu), cobalt (Co), molybdenum (Mo), tungsten (W), or ruthenium (Ru), and
the second conductive material comprises copper (Cu), cobalt (Co), ruthenium (Ru), or molybdenum (Mo).
